(19) United States
(12) Patent Application Publication
(10) Pub. No.: US 2026/0335942 A1
(43) Pub. Date: Oct. 29, 2026

(54) BASE MATERIAL CLEANING APPARATUS

(71) Applicants: TMEIC Corporation, Tokyo (JP); TOYOTA JIDOSHA KABUSHIKI KAISHA, Toyota-shi, Aichi (JP)

(72) Inventors: Kohsei GOTOH, Tokyo (JP); Takahiro HIRAMATSU, Tokyo (JP); Hiroyuki ORITA, Tokyo (JP); Akihiro ICHINOSE, Tokyo (JP); Nobuyoshi NAMITO, Tokyo (JP); Hiroshi YANAGIMOTO, Miyoshi-shi, Aichi (JP); Keiji KURODA, Toyota-shi, Aichi (JP); Rentaro MORI, Kasugai-shi, Aichi (JP)

(73) Assignees: TMEIC Corporation, Tokyo (JP); TOYOTA JIDOSHA KABUSHIKI KAISHA, Toyota-shi, Aichi (JP)

(21) Appl. No.: 19/119,790

(22) PCT Filed: Sep. 21, 2023
(86) PCT No.: PCT/JP2023/034315

§ 371 Date: Apr. 10, 2025

(51) Int. Cl. B08B 3/02; B08B 3/12; B08B 5/02

(52) U.S. Cl. CPC B08B 3/022; B08B 3/12; B08B 5/023

(57) ABSTRACT

A mist jet jets a relay mist gas containing cleaning solution mist along a mist jet direction. An air knife performs first air gas blowing of blowing an air gas toward the relay mist gas along an air gas blowing direction to merge the air gas with the relay mist gas to thereby obtain a cleaning mist gas during transport operation of transporting a base material performed by a transport means. The cleaning mist gas supplied by the first air gas blowing is blown directly onto a front surface of the base material being transported.

### TECHNICAL FIELD

The present disclosure relates to a base material cleaning apparatus that cleans a base material and, for example, to a base material cleaning apparatus that cleans a base material for use in a plating apparatus that forms a metal coating during manufacture of electronic components and the like.

### BACKGROUND ART

Examples of a conventional cleaning apparatus that cleans a base material and the like for use in a plating apparatus that forms a metal coating during manufacture of electronic components and the like include a hermetic cleaning apparatus disclosed in Patent Document 1, a substrate liquid treatment apparatus disclosed in Patent Document 2, a substrate cleaning apparatus disclosed in Patent Document 3, a cleaning apparatus disclosed in Patent Document 4, and a cleaning apparatus disclosed in Patent Document 5.

Each of the cleaning apparatuses disclosed in Patent Documents 1 to 3 basically injects a cleaning solution directly onto a cleaning target to clean the cleaning target. The cleaning apparatus disclosed in Patent Document 4 performs cleaning in a mist atmosphere. The cleaning apparatus disclosed in Patent Document 5 injects a cleaning solution directly onto a cleaning target placed in a mist atmosphere for cleaning.

### PRIOR ART DOCUMENTS

### Patent Documents

Patent Document 1: Japanese Patent Application Laid-Open No. 11-76962
Patent Document 2: WO 2018/501665
Patent Document 3: Japanese Patent Application Laid-Open No. 2009-136742
Patent Document 4: Japanese Patent Application Laid-Open No. 2020-18993
Patent Document 5: Japanese Patent Application Laid-Open No. 2007-33730

### SUMMARY

### Problem to be Solved by the Invention

Each of the conventional cleaning apparatuses disclosed in Patent Documents 1 to 5 basically injects a cleaning solution including a misted cleaning solution directly onto a cleaning target and thus has a problem in that a large quantity of the cleaning solution is used.

The present disclosure has been conceived to solve a problem as described above, and it is an object of the present disclosure to provide a base material cleaning apparatus that can suppress the quantity of a used cleaning solution.

### Means to Solve the Problem

A base material cleaning apparatus according to the present disclosure includes: a transport means that performs transport operation of transporting a base material along a transport direction; and a mist gas supply mechanism that supplies a cleaning mist gas containing cleaning solution mist obtained by misting a cleaning solution to clean a cleaning surface of the base material, wherein the mist gas supply mechanism includes: a mist jet that jets a relay mist gas containing the cleaning solution mist along a mist jet direction; and a first air gas blower that performs first air gas blowing of blowing a first air gas toward the relay mist gas along a first air gas blowing direction to merge the first air gas with the relay mist gas to thereby obtain the cleaning mist gas during the transport operation performed by the transport means, the cleaning mist gas is supplied to the cleaning surface of the base material by the first air gas blowing, and a flow rate of the relay mist gas is set to an initial mist flow rate, a flow rate of the first air gas is set to a first air gas flow rate, and the first air gas flow rate is set to be higher than the initial mist flow rate.

### Effects of the Invention

The mist gas supply mechanism of the base material cleaning apparatus according to the present disclosure includes the mist jet and the first air gas blower described above, and the first air gas flow rate is set to be higher than the initial mist flow rate.

The cleaning mist gas obtained by merging the relay mist gas and the first air gas is thus affected by the first air gas, a direction in which the cleaning mist gas is supplied becomes identical to the first air gas blowing direction, and an ultimate mist gas flow rate as a flow rate of the cleaning mist gas becomes similar to the first air gas flow rate.

The first air gas flow rate is thus set to a flow rate necessary to clean the cleaning surface of the base material, so that the cleaning solution mist can efficiently be supplied to the cleaning surface of the base material while the amount of the cleaning solution mist contained in the cleaning mist gas is minimized.

As a result, the base material cleaning apparatus according to the present disclosure can remove an object-to-be-removed adhering to the cleaning surface of the base material while suppressing the quantity of a used cleaning solution.

These and other objects, features, aspects and advantages of the present disclosure will become more apparent from the following detailed description when taken in conjunction with the accompanying drawings.

### BRIEF DESCRIPTION OF DRAWINGS

FIG. 1 is a schematic illustration of an overall configuration of a base material cleaning apparatus according to Embodiment 1.

FIG. 2 is a schematic illustration of a configuration of a mist gas supply mechanism illustrated in FIG. 1.

FIG. 3 is a schematic illustration of an air knife in a draining mechanism illustrated in FIG. 1 and its surroundings.

FIG. 4 is a schematic illustration of a function of adjusting an air knife in the mist gas supply mechanism.

FIG. 5 is a schematic illustration of a function of adjusting a mist jet in the mist gas supply mechanism.

FIG. 6 is a block diagram showing a configuration to achieve the functions of adjusting the mist jet and the air knife illustrated in FIGS. 4 and 5.

FIG. 7 is an illustration of an anti-mist diffusion plate illustrated in FIG. 1 and its surroundings.

FIG. 8 is an illustration of a planar configuration of the anti-mist diffusion plate.

FIG. 9 is an illustration of a configuration of a comparative base material cleaning apparatus.

FIG. 10 is a schematic illustration of an overall configuration of a base material cleaning apparatus according to Embodiment 2.

FIG. 11 is a schematic illustration of a configuration of a mist gas supply mechanism illustrated in FIG. 10.

FIG. 12 is an illustration of a structure of an adsorption mechanism illustrated in FIGS. 10 and 11.

### DESCRIPTION OF EMBODIMENTS

### Introduction

A base material cleaning apparatus according to the present disclosure is an apparatus that cleans a base material and, for example, is an apparatus that cleans a base material for use in a plating apparatus that forms a metal coating during manufacture of electronic components and the like. A more specific example includes a base material cleaning apparatus that cleans, as a cleaning target, a plating solution adhering to a treated base material, such as a metal base material and a printed circuit board, after the end of plating in a plating step. For example, a base material 1 after plating includes a plated region and a non-plated region in which a plating solution remains, and plating solutions remaining in the former and the latter regions are both cleaning targets to be removed.

### Embodiment 1

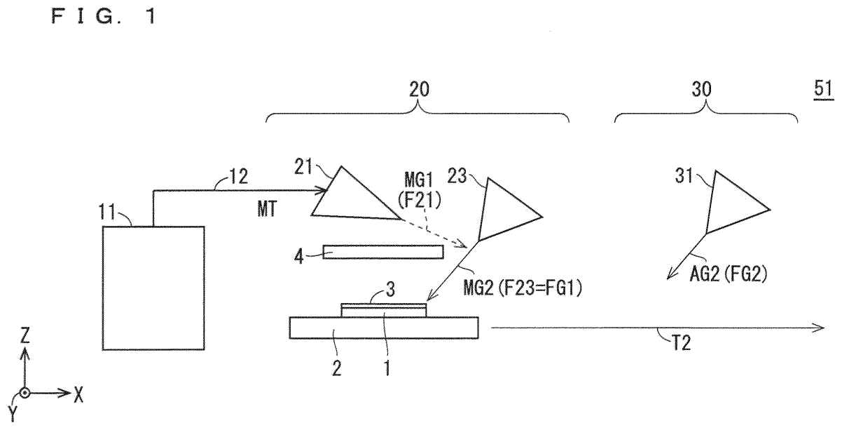

FIG. 1 is a schematic illustration of an overall configuration of a base material cleaning apparatus 51 according to Embodiment 1. The figure includes an XYZ Cartesian coordinate system.

As illustrated in the figure, the base material 1 is mounted on a transport table 2, and an object-to-be-removed 3, such as a plating solution, adheres to a front surface of the base material 1. The object-to-be-removed 3 is a cleaning target of the base material cleaning apparatus 51. In Embodiment 1, the front surface of the base material 1 is a cleaning surface, and a plating solution adhering to the front surface of the base material 1 is assumed as the object-to-be-removed 3.

The base material cleaning apparatus 51 includes a transport means, an ultrasonic atomizer 11, mist supply piping 12, a mist gas supply mechanism 20, and a draining mechanism 30 as main components.

The transport means includes the above-mentioned transport table 2 and an unillustrated transporter, such as a conveyor. The transport means performs transport operation of transporting the base material 1 along a table transport direction T2 (+X direction) by moving the transport table 2 along the table transport direction T2 using the transporter.

The ultrasonic atomizer 11 contains therein a cleaning solution (not illustrated) and applies an ultrasonic vibration to the cleaning solution to generate cleaning solution mist MT having a particle diameter (of a droplet) of 15 μm or less. The cleaning solution mist MT generated by the ultrasonic atomizer 11 is supplied by a transport gas (not illustrated) to a mist jet 21 of the mist gas supply mechanism 20 via the mist supply piping 12. Pure water is used as the cleaning solution in Embodiment 1.

As technology of generating the cleaning solution mist MT other than that of an ultrasonic propagation scheme of applying an ultrasonic vibration to the cleaning solution, generation technology of pressure, rotary, steam, piezo, thermal, and electrostatic schemes and the like is contemplated. It is, however, desirable to use the ultrasonic vibration propagation scheme when the cleaning solution mist MT having a relatively small particle diameter (of a droplet) of 15 μm or less is generated.

The mist gas supply mechanism 20 supplies a cleaning mist gas MG2 containing the cleaning solution mist MT obtained by misting the cleaning solution onto the front surface as the cleaning surface of the base material 1 to clean the object-to-be-removed 3 adhering to the front surface of the base material 1.

The mist gas supply mechanism 20 includes the mist jet 21 and an air knife 23 as a first air gas blower as main components.

The mist jet 21 jets a relay mist gas MG1 containing the cleaning solution mist MT along a mist jet direction F21. In this case, the relay mist gas MG1 is supplied to an air outlet of an air gas AG1 of the air knife 23 or surroundings of the air outlet. A flow rate of the relay mist gas MG1 is herein referred to as a mist gas flow rate V21. The mist gas flow rate V21 is an initial mist flow rate.

The mist jet 21 is achieved by transporting the cleaning solution mist MT using a jetting transport gas (not illustrated) having directionality along the mist gas jet direction F21, for example. In this case, a mixture of the cleaning solution mist MT and the transport gas is the relay mist gas MG1.

The particle diameter of the cleaning solution mist MT generated by the ultrasonic atomizer 11 applying the ultrasonic vibration is 15 μm or less and is smaller than a particle diameter of typical spray mist, and a fall speed of the cleaning solution mist MT is low, so that the cleaning solution mist MT can be treated, as the relay mist gas MG1, in a state of being entrained in a gas flow having directionality in the mist gas jet direction F21.

The air knife 23 as the first air gas blower performs first air gas blowing of blowing the air gas AG1 toward the relay mist gas MG1 along an air gas blowing direction FG1 to merge the air gas AG1 with the relay mist gas MG1 to thereby obtain the cleaning mist gas MG2 during the above-mentioned transport operation performed by the above-mentioned transport means. The air gas AG1 is a first air gas, and air, nitrogen, and the like are used as the air gas AG1.

A flow rate of the air gas AG1 as the first air gas is herein referred to as an air gas flow rate VG1 (a first air gas flow rate), and the air gas flow rate VG1 is set to be higher than the mist gas flow rate V21. Specifically, a ratio {VG1:V21} of the air gas flow rate VG1 to the mist gas flow rate V21 is set to {10:1}, for example.

Since the air gas flow rate VG1 is set to be higher than the mist gas flow rate V21 as described above, the relay mist gas MG1 is entrained into a flow of the air gas AG1 when being merged with the air gas AG1 and is thus greatly affected by the air gas AG1.

Herein, a flow rate of the cleaning mist gas MG2 is referred to as a mist gas flow rate V23, and a direction in which the cleaning mist gas MG2 is supplied is referred to as a mist gas supply direction F23. Since the cleaning mist gas MG2 is greatly affected by the air gas AG1 as described above, the mist gas supply direction F23 becomes identical to the air gas blowing direction FG1, and the mist gas flow rate V23 becomes similar to the air gas flow rate VG1. This is because the mist gas flow rate V21 of the relay mist gas MG1 is lower than the air gas flow rate VG1 of the air gas AG1, and thus the Coandă effect occurs.

As described above, as for the cleaning mist gas MG2 obtained by merging the relay mist gas MG1 and the air gas AG1, the mist gas supply direction F23 becomes identical to the air gas blowing direction FG1, and the mist gas flow rate V23 becomes similar to the air gas flow rate VG1.

The cleaning mist gas MG2 obtained by merging the air gas AG1 with the relay mist gas MG1 flows below an anti-mist diffusion plate 4, which will be described below, and is supplied toward a transport path of the transport table 2 transported along the table transport direction T2.

The cleaning mist gas MG2 supplied by the first air gas blowing is thus blown directly onto the front surface of the base material 1 during the transport operation performed by the transport means.

In this case, the mist gas flow rate V23 of the cleaning mist gas MG2 becomes similar to the air gas flow rate VG1 of the air gas AG1, so that the cleaning mist gas MG2 is blown directly onto the object-to-be-removed 3 adhering to the front surface of the base material 1 at the mist gas flow rate V23, which is a relatively high flow rate. The cleaning mist gas MG2 having the mist gas flow rate V23 can thus wash away the object-to-be-removed 3, such as the plating solution.

As a result, the cleaning mist gas MG2 containing the cleaning solution mist MT is blown onto the front surface of the base material 1, and the object-to-be-removed 3 adhering to the front surface of the base material 1 is removed or decomposed to consequently clean the object-to-be-removed 3 as the cleaning target.

The draining mechanism 30 includes an air knife 31 as a main component. The air knife 31 as a second air gas blower is disposed downstream of the air knife 23 as the first air gas blower in the table transport direction T2.

An air gas AG2 blown by the air knife 31 as the second air gas blower along an air gas blowing direction FG2 flows below the anti-mist diffusion plate 4 and is supplied toward the transport path of the transport table 2 transported along the table transport direction T2 during the above-mentioned transport operation performed by the above-mentioned transport means.

The air knife 31 as the second air gas blower performs second air gas blowing of blowing the air gas AG2 as a second air gas directly onto a remaining object remaining on the front surface of the base material 1 during the above-mentioned transport operation performed by the above-mentioned transport means.

The air gas blowing direction FG1 (mist gas supply direction F23) of the air gas AG1 and the air gas blowing direction FG2 of the air gas AG2 each have a directional component in a transport opposite direction (−X direction) opposite the table transport direction T2.

The remaining object remaining on the front surface of the base material 1 can be removed by the second air gas blowing performed by the air knife 31. As the remaining object, a portion of the object-to-be-removed 3, a cleaning solution, and the like are contemplated.

While the table transport direction T2 for the base material 1 is a horizontal direction (X direction) in FIG. 1, the table transport direction T2 may be a direction inclined to the X direction or may be a vertical direction (Z direction).

While the cleaning surface of the base material 1 is the front surface (an upper surface) of the base material in FIG. 1, the cleaning surface may be a rear surface (lower surface) of the base material 1.

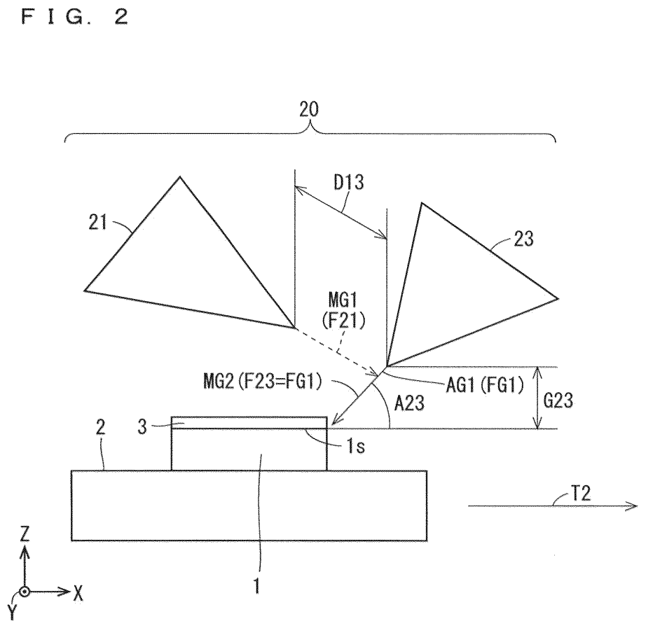

FIG. 2 is a schematic illustration of a configuration of the mist gas supply mechanism 20. As illustrated in the figure, a distance until the relay mist gas MG1 is merged with the air gas AG1 along the mist gas jet direction F21 is an inter-output port distance D13. The inter-output port distance D13 is a distance from a jet outlet (leading end portion) of the mist jet 21 to a region around an air outlet (leading end portion) of the air knife 23. The inter-output port distance D13 is set so that the relay mist gas MG1 and the air gas AG1 merge to obtain the cleaning mist gas MG2 having directionality in the mist gas supply direction F23 matching the air gas blowing direction FG1 with accuracy.

A gap G23 as a distance from a front surface 1s as the cleaning surface of the base material 1 to the air outlet of the air knife 23 along the vertical direction (Z direction) is set to have a length that increases an effect of removing the object-to-be-removed 3.

A gas flow supply angle A23 as an angle of the mist gas supply direction F23 relative to the table transport direction T2 (+X direction) is set in a range of 0° to 90° (more than 0° and less than 90°:0(°)<A23<90(°)). The gas flow supply angle A23 is a first air gas blowing angle.

Setting the gas flow supply angle A23 as the first air gas blowing angle to an angle out of the range of 0° to 90° is not desirable because, when the object-to-be-removed 3 is washed away for removal, the object-to-be-removed 3 can flow on the front surface as the cleaning surface of the base material 1 to contaminate the front surface of the base material 1.

When the air gas AG1 is blown by the air knife 23, a gas supply pressure to the air knife 23 is set to a pressure at which a desired air gas flow rate VG1 can be obtained.

It is desirable to set a transport speed of the base material 1 by the transport means along the table transport direction T2 appropriately within a range in which the amount of used cleaning solution mist MT contained in the cleaning mist gas MG2 is suppressed and an effect of cleaning the object-to-be-removed 3 is maintained moderately.

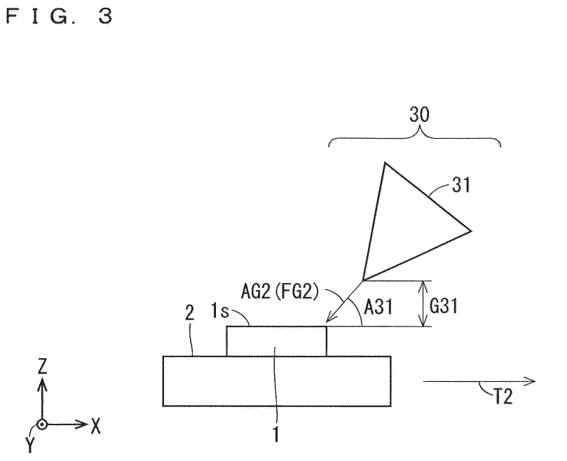

FIG. 3 is a schematic illustration of the air knife 31 and its surroundings. An air gas flow rate VG2 (a second air gas flow rate) of the air gas AG2 (second air gas) blown by the air knife 31 as the second air gas blower is set so that an effect of removing the remaining object on the front surface of the base material 1 is maintained at a desired removal level, and a degree of dryness of the front surface of the base material 1 is at a predetermined dryness level or less.

The effect of removing the remaining object increases with increasing air gas flow rate VG2 as the second air gas flow rate, and the degree of dryness of the front surface of the base material 1 can be suppressed to be low as the air gas flow rate VG2 decreases. When the base material 1 is a material prone to oxidation, an increase in degree of dryness of the front surface of the base material 1 can cause oxidation of the remaining object on the front surface of the base material 1 to contaminate the base material 1. The air gas flow rate VG2 can be adjusted by a gas supply pressure to the air knife 31.

A gap G31 from the front surface as the cleaning surface of the base material 1 to an air outlet of the air knife 31 along the vertical direction (Z direction) is set to a distance that produces a high effect of removing the remaining object and prevents movement of the base material 1 mounted on the transport table 2. A decrease in gap G31 can increase wind power by the air gas AG2 and cause the base material 1 to move from the transport table 2.

A gas flow supply angle A31 as an angle of the air gas blowing direction FG2 relative to the table transport direction T2 (X direction) is set in a range of 0° to 90° (more than 0° and less than 90°:0(°)<A31<90(°)). The gas flow supply angle A23 is a second air gas blowing angle.

Setting the gas flow supply angle A31 as the second air gas blowing angle to an angle out of the range of 0° to 90° is not desirable because, when the remaining object is washed away for removal, the remaining object can flow on the front surface as the cleaning surface of the base material 1 to contaminate the front surface of the base material 1.

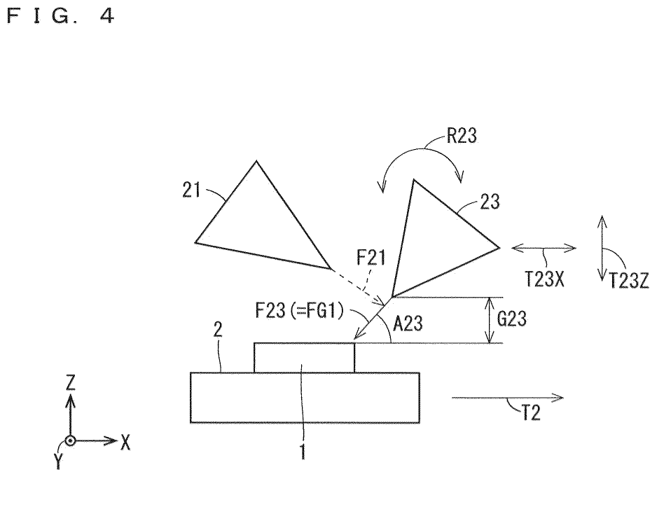

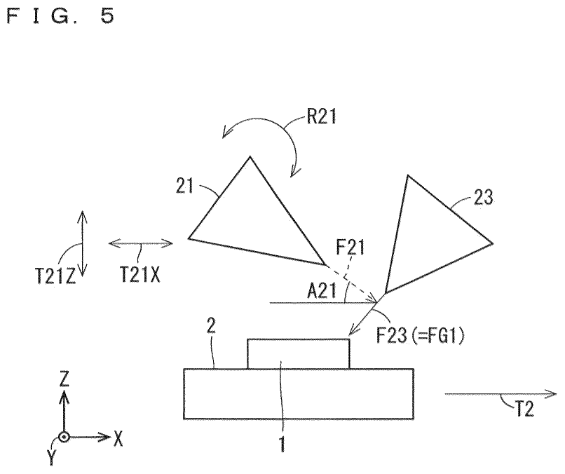

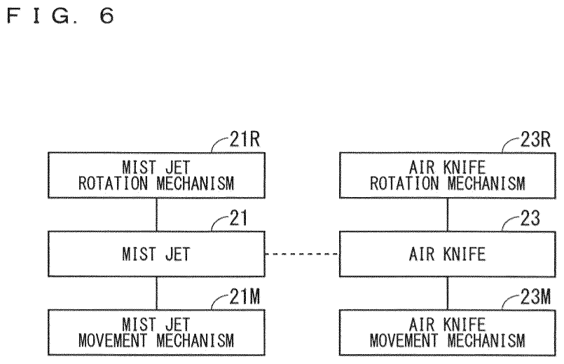

FIG. 4 is a schematic illustration of a function of adjusting the air knife 23. FIG. 5 is a schematic illustration of a function of adjusting the mist jet 21. FIG. 6 is a block diagram showing a configuration to achieve the functions of adjusting the mist jet 21 and the air knife 23.

As shown in FIG. 6, an air knife rotation mechanism 23R and an air knife movement mechanism 23M are connected to the air knife 23.

The air knife movement mechanism 23M is a mechanism that moves the air knife 23 along a movement direction T23X or a movement direction T23Z. The base material cleaning apparatus 51 including the air knife movement mechanism 23M thus has a first blower movement function of moving the air knife 23 as the first air gas blower along the movement direction T23X or the movement direction T23Z. The movement direction T23X is a direction parallel to the X direction, and the movement direction T23Z is a direction parallel to the Z direction.

The air knife rotation mechanism 23R is a mechanism that rotates the air knife 23 along a rotation direction R23 around a predetermined location of the air knife 23 as an axis of rotation in an XZ plane. The base material cleaning apparatus 51 including the air knife rotation mechanism 23R thus has a first blowing angle adjustment function of adjusting the gas flow supply angle A23 as the first air gas blowing angle by rotating the air knife 23 along the rotation direction R23.

The air knife movement mechanism 23M may have any configuration as long as the air knife 23 can be moved without changing the gas flow supply angle A23 and can be achieved by existing technology. The air knife rotation mechanism 23R may have any configuration as long as the air knife 23 can be rotated along the rotation direction R23 and can be achieved by existing technology.

As shown in FIG. 6, a mist jet rotation mechanism 21R and a mist jet movement mechanism 21M are connected to the mist jet 21.

The mist jet movement mechanism 21M is a mechanism that moves the mist jet 21 along a movement direction T21X or a movement direction T21Z. The base material cleaning apparatus 51 including the mist jet movement mechanism 21M thus has a jet movement function of moving the mist jet 21 along the movement direction T21X or the movement direction T23Z. The movement direction T21X is a direction parallel to the X direction, and the movement direction T21Z is a direction parallel to the Z direction.

The mist jet rotation mechanism 21R is a mechanism that rotates the mist jet 21 along a rotation direction R21 around a predetermined location of the mist jet 21 as an axis of rotation in the XZ plane. The base material cleaning apparatus 51 including the mist jet rotation mechanism 21R thus has a jet angle adjustment function of adjusting a mist supply angle A21 as a mist jet angle relative to the table transport direction T2 by rotating the mist jet 21 along the rotation direction R21. The mist supply angle A21 is set in a range of 0° to 90° (more than 0° and less than 90°:0(°)<A21<90(°)).

The mist jet movement mechanism 21M may have any configuration as long as the mist jet 21 can be moved without changing the mist supply angle A21 and can be achieved by existing technology. The mist jet rotation mechanism 21R may have any configuration as long as the air knife 23 can be rotated along the rotation direction R21 and can be achieved by existing technology.

### Anti-Mist Diffusion Plate 4

The base material cleaning apparatus 51 according to Embodiment 1 includes the anti-mist diffusion plate 4. The anti-mist diffusion plate 4 is disposed between the mist gas supply mechanism 20 and the base material 1 and is planar. The planar shape is a shape along an XY plane.

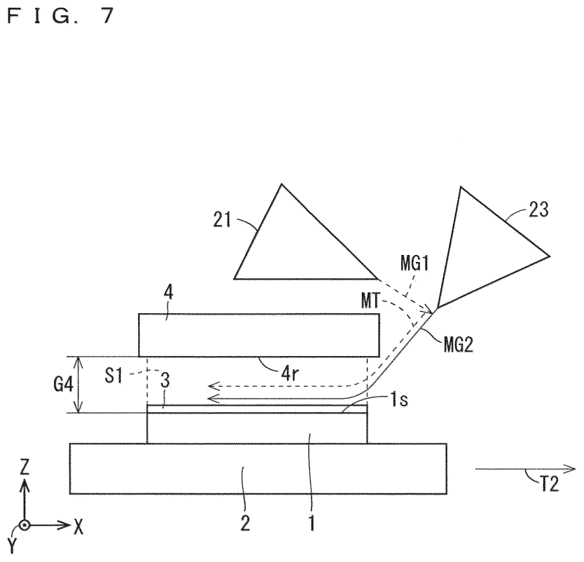

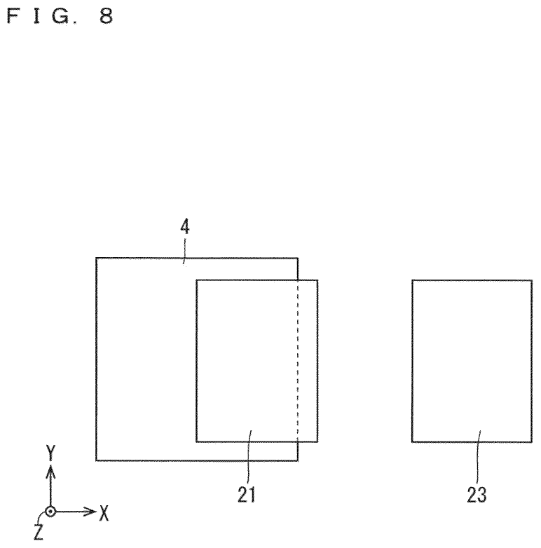

FIG. 7 is an illustration of the anti-mist diffusion plate 4 and its surroundings, and FIG. 8 is an illustration of a planar configuration of the anti-mist diffusion plate 4. FIGS. 7 and 8 each include the XYZ Cartesian coordinate system.

The anti-mist diffusion plate 4 is disposed to provide a diffusion suppression space S1 having a gap G4 as a predetermined gap without interfering with supply of the cleaning mist gas MG2 to the front surface 1s as the cleaning surface of the base material 1. The gap G4 is a distance between a rear surface 4r of the anti-mist diffusion plate 4 and the front surface 1s of the base material 1 along the Z direction, and the diffusion suppression space S1 is a space that is formed between the front surface 1s of the base material 1 and the rear surface 4r of the anti-mist diffusion plate 4 and has the gap G4.

As illustrated in FIG. 8, the anti-mist diffusion plate 4 is set to have a sufficiently large planar shape, so that a large portion of a space above the front surface 1s of the base material 1 can be the diffusion suppression space S1.

The gap G4 as the predetermined gap is set to be sufficiently short to cause the diffusion suppression space S1 to be a narrow space, so that diffusion of the cleaning solution mist MT contained in the cleaning mist gas MG2 can be suppressed. It is desirable to set the gap G4 (μm) in a range satisfying {15 μm<G4≤50 mm}.

That is to say, in the base material cleaning apparatus 51 according to Embodiment 1, the cleaning solution mist MT is assumed to have a particle diameter (of a droplet) of 15 μm or less, and the gap G4 is set to have a length exceeding the particle diameter of the cleaning solution mist MT.

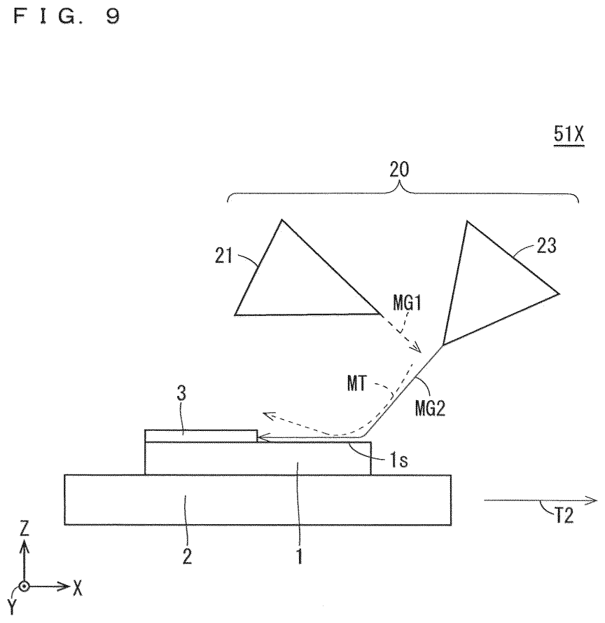

FIG. 9 is an illustration of a configuration of a comparative base material cleaning apparatus 51X based on the assumption that the anti-mist diffusion plate 4 is absent from the base material cleaning apparatus 51 according to Embodiment 1. The figure includes the XYZ Cartesian coordinate system. FIG. 9 illustrates a state of the object-to-be-removed 3 adhering to a portion of the front surface of the base material 1.

As illustrated in the figure, when the cleaning mist gas MG2 is supplied to the front surface 1s of the base material 1, a portion of the cleaning solution mist MT contained in the cleaning mist gas MG2 diffuses above the base material 1 as the cleaning solution mist MT is lightweight. The comparative base material cleaning apparatus 51X does not include the anti-mist diffusion plate 4 and thus cannot suppress a phenomenon of diffusion of the cleaning solution mist MT.

The cleaning mist gas MG2 thus becomes a drier gas due to diffusion of the cleaning solution mist MT, so that the front surface 1s of the base material 1 is likely to be dried as a result of the cleaning mist gas MG2 in a dried state being blown onto the front surface 1s of the base material 1. The front surface 1s of the base material 1 in a dried state is contaminated upon being oxidized.

On the other hand, in the base material cleaning apparatus 51 according to Embodiment 1, the space above the front surface 1s of the base material 1 is narrowed to the diffusion suppression space S1 due to the presence of the anti-mist diffusion plate 4, so that diffusion of the cleaning solution mist MT contained in the cleaning mist gas MG2 can effectively be suppressed. The base material cleaning apparatus 51 according to Embodiment 1 can thus avoid a phenomenon of contamination of the front surface 1s due to oxidation by suppressing drying of the front surface 1s.

### Effects

The mist gas supply mechanism 20 of the base material cleaning apparatus 51 according to Embodiment 1 of the present disclosure includes the mist jet 21 and the air knife 23, and the air gas flow rate VG1 as the first air gas flow rate is set to be higher than the mist gas flow rate V21 of the relay mist gas MG1.

The cleaning mist gas MG2 obtained by merging the air gas AG1 with the relay mist gas MG1 is thus affected by the air gas AG1, so that the mist gas supply direction F23 of the cleaning mist gas MG2 becomes identical to the air gas blowing direction FG1, and the mist gas flow rate V23 becomes similar to the air gas flow rate VG1.

The air gas flow rate VG1 is thus set to a flow rate necessary to clean the front surface 1s as the cleaning surface of the base material 1, so that the cleaning solution mist MT can efficiently be supplied to the front surface of the base material 1 while the amount of cleaning solution mist MT contained in the cleaning mist gas MG2 is minimized.

As a result, the base material cleaning apparatus 51 according to Embodiment 1 can remove the object-to-be-removed 3 adhering to the front surface of the base material 1 while suppressing the quantity of a used cleaning solution.

The base material cleaning apparatus 51 according to Embodiment 1 supplies the cleaning mist gas MG2 onto the transport path of the transport table 2 and blows the cleaning mist gas MG2 containing the cleaning solution mist MT directly onto the front surface of the base material 1 to remove the object-to-be-removed 3 adhering to the front surface of the base material 1 with accuracy.

A practical example of a cleaning effect produced by the base material cleaning apparatus 51 according to Embodiment 1 when the object-to-be-removed 3 was a nickel plating solution and the cleaning solution was pure water will be shown below.

The base material 1 was a Hull cell copper base material having a planar size of 100 mm×100 mm and a thickness of 0.3 mm, and 2 mL of the nickel plating solution was added drop-wise to the front surface as the cleaning surface and was spread to remove a unnecessary plating solution. As described above, the nickel plating solution having a weight of 0.6 g to 0.7 g and a thickness of approximately 0.5 mm was caused to adhere, as the object-to-be-removed 3, to the front surface of the base material 1.

For the base material 1 having the front surface to which the object-to-be-removed 3 had adhered as described above, the mist gas supply mechanism 20 blew the cleaning mist gas MG2 onto the front surface of the base material 1, and the remaining object on the front surface of the base material 1 was removed using the air knife 31 during the transport operation performed by the transport means of transporting the transport table 2 along the table transport direction T2 at a base material transport speed of 200 mm/min.

As a result, in the base material cleaning apparatus 51 according to Embodiment 1, an analytical result showing that the quantity of an adhering nickel plating solution as the object-to-be-removed 3 had been reduced to 22 μg was obtained by inductively coupled plasma mass spectrometry (ICP-MS).

As described above, the base material cleaning apparatus 51 according to Embodiment 1 can remove the object-to-be-removed 3 adhering to the front surface of the base material 1 with accuracy.

The object-to-be-removed 3 adhering to the front surface of the base material 1 can be removed only by forming an atmosphere of the cleaning mist gas MG2 on the front surface of the transport table 2 without blowing the cleaning mist gas MG2 directly onto the front surface of the base material 1. For example, an indirect supply environment of the cleaning mist gas MG2 in which the transport path of the transport table 2 is provided leeward of the cleaning mist gas MG2 and the front surface of the base material 1 passes through the atmosphere of the cleaning mist gas MG2, for example, is contemplated.

To increase the cleaning effect of removing the object-to-be-removed 3, however, an environment in which the cleaning mist gas MG2 is blown directly onto the front surface of the base material 1 is more desirable than the indirect supply environment of the cleaning mist gas MG2.

In the base material cleaning apparatus 51 according to Embodiment 1, the air knife 31 as the second air gas blower blows the air gas AG2 as the second air gas directly onto the front surface 1s as the cleaning surface of the base material 1 to remove the remaining object remaining on the front surface 1s of the base material 1 with accuracy.

The base material cleaning apparatus 51 according to Embodiment 1 includes the ultrasonic atomizer 11, so that the cleaning solution mist MT having a relatively small particle diameter of 15 μm or less, for example, can be supplied to the mist jet 21 via the mist supply piping 12.

As a result, the cleaning solution mist MT contained in the cleaning mist gas MG2 supplied from the base material cleaning apparatus 51 according to Embodiment 1 can enter a fine portion in the front surface of the base material 1, and the quantity of a cleaning solution contained in a droplet of one unit of the cleaning solution mist MT can be suppressed to minimize the quantity of the used cleaning solution.

As for the air knife 23 of the base material cleaning apparatus 51 according to Embodiment 1, the air gas blowing direction FG1 (mist gas supply direction F23) has the directional component in the transport opposite direction opposite the table transport direction T2, and the gas flow supply angle A23 as the first air gas blowing angle is set in a range of 0° to 90° (0(°) A23<90(°)).

The base material cleaning apparatus 51 according to Embodiment 1 can thus remove the object-to-be-removed 3 adhering to the front surface of the base material 1 with accuracy.

The base material cleaning apparatus 51 according to Embodiment 1 has the first blower movement function achieved by the air knife movement mechanism 23M and the first blowing angle adjustment function achieved by the air knife rotation mechanism 23R.

The base material cleaning apparatus 51 according to Embodiment 1 can thus adjust a location where the relay mist gas MG1 and the air gas AG2 merge and the air gas blowing direction FG1 (=the mist gas supply direction F23) to increase the effect of removing the object-to-be-removed 3 adhering to the front surface of the base material 1.

As for the mist jet 21 of the base material cleaning apparatus 51 according to Embodiment 1, the mist gas jet direction F21 includes a directional component in the table transport direction T2 (+X direction), and the mist supply angle A21 as the mist jet angle relative to the table transport direction T2 is set in a range of 0° to 90° (0(°)<A21<90 (°)). On the other hand, as for the air knife 23 as the first air gas blower, the air gas blowing direction FG1 as the first air gas blowing direction includes the directional component in the transport opposite direction (−X direction), and the gas flow supply angle A23 as the first air gas blowing angle is set in a range of 0° to 90°.

The air knife 23 of the base material cleaning apparatus 51 according to Embodiment 1 can thus relatively easily perform the first air gas blowing toward the relay mist gas MG1 jetted from the mist jet 21.

In a preferred aspect of the present embodiment, the mist supply angle A21 is set in a range of 0° to 90° including the directional component in the table transport direction T2 to enable supply to the air outlet of the air gas AG1 of the air knife 23 or the surroundings of the air outlet. In a modification, it is contemplated that the mist supply angle A21 is set to an angle other than 0° to 90°. Since the cleaning mist gas MG2 is greatly affected by the air gas AG1 as described above, the cleaning mist gas MG2 directly blown onto the object-to-be-removed 3 can be obtained by the air gas AG1 also in the modification.

The base material cleaning apparatus 51 according to Embodiment 1 has the jet movement function performed by the mist jet movement mechanism 21M and the jet angle adjustment function performed by the mist jet rotation mechanism 21R.

The base material cleaning apparatus 51 according to Embodiment 1 can thus adjust the location where the relay mist gas MG1 and the air gas AG2 merge to increase the effect of removing the object-to-be-removed 3 adhering to the front surface of the base material 1.

The anti-mist diffusion plate 4 of the base material cleaning apparatus 51 according to Embodiment 1 is disposed to provide the diffusion suppression space S1 having the gap G4 as the predetermined gap between the anti-mist diffusion plate 4 and the front surface 1s of the base material 1 without interfering with supply of the cleaning mist gas MG2 to the front surface 1s as the cleaning surface of the base material 1.

The base material cleaning apparatus 51 according to Embodiment 1 can restrict a space with which the front surface 1s of the base material 1 is in contact to the diffusion suppression space S1, which is a relatively narrow space, using the anti-mist diffusion plate 4 to produce a mist diffusion suppression effect of effectively suppressing a phenomenon of diffusion of the cleaning solution mist MT contained in the cleaning mist gas MG2 from the front surface 1s of the base material 1.

When the air gas flow rate VG1 of the air gas AG1 blown by the air knife 23 is high, the mist gas flow rate V23 (=VG1) of the cleaning mist gas MG2 is also high, so that the cleaning solution mist MT in the cleaning mist gas MG2 is less likely to adhere to the front surface 1s of the base material 1. A rate of adhesion of the cleaning solution mist MT to the front surface 1s of the base material 1, however, can be increased by the above-mentioned mist diffusion suppression effect produced due to the presence in the diffusion suppression space S1, which is a relatively narrow space.

As a result, the base material cleaning apparatus 51 according to Embodiment 1 can avoid, due to the above-mentioned mist diffusion suppression effect, oxidation of the front surface 1s as the cleaning surface of the base material 1 due to drying to remove the object-to-be-removed 3 without contaminating the front surface 1s.

In the base material cleaning apparatus 51 according to Embodiment 1, the gap G4 (predetermined gap) having the length exceeding the particle diameter of the cleaning solution mist MT is set. In Embodiment 1, the cleaning solution mist MT is obtained by the ultrasonic atomizer 11, so that the gap G4 is set to have a length of more than 15 μm. This is because the cleaning solution mist MT generated by the ultrasonic atomizer 11 has a particle diameter of 15 μm or less.

It is desirable to set the gap G4 in a range satisfying {15 μm<G4≤50 mm} not to reduce the above-mentioned mist diffusion suppression effect. That is to say, it is desirable to set an upper limit of the gap G4 to approximately 50 mm.

The base material cleaning apparatus 51 according to Embodiment 1 can thus supply the cleaning solution mist MT contained in the cleaning mist gas MG2 to the diffusion suppression space S1 having the gap G4, which is a relatively small gap, without any obstructions.

### Embodiment 2

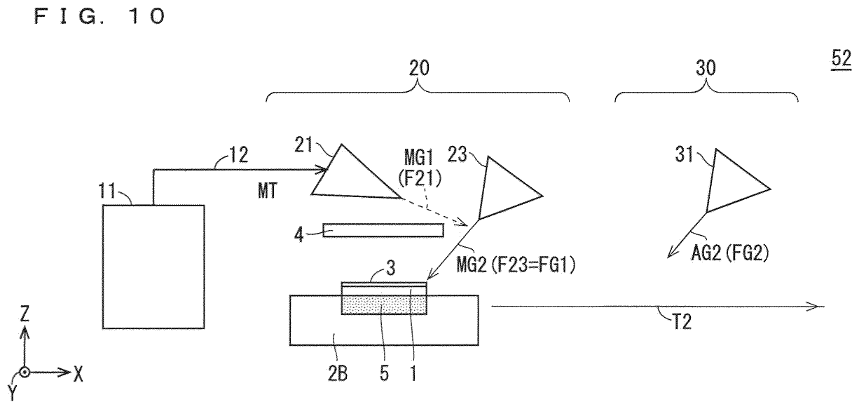

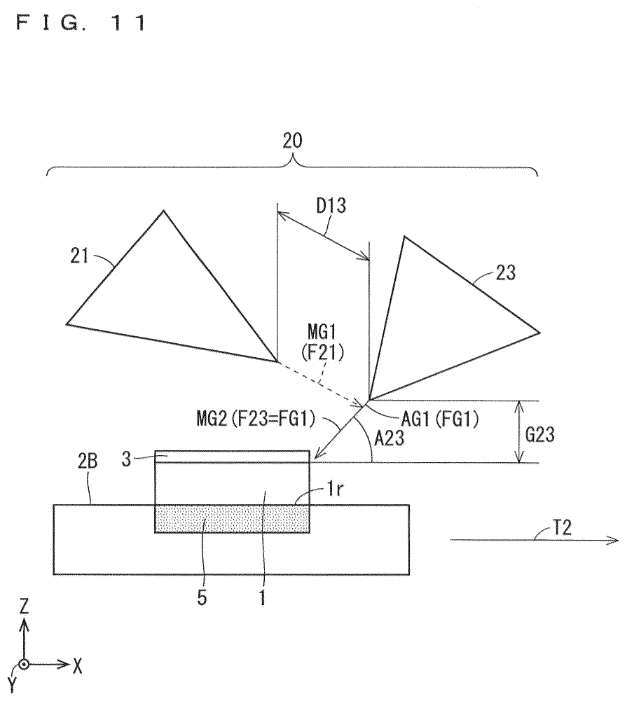

FIG. 10 is a schematic illustration of an overall configuration of a base material cleaning apparatus 52 according to Embodiment 2. FIG. 11 is a schematic illustration of a configuration of the mist gas supply mechanism 20. FIGS. 10 and 11 each include the XYZ Cartesian coordinate system.

Components similar to those of the base material cleaning apparatus 51 according to Embodiment 1 hereinafter bear the same reference signs as those of the similar components, and description will be made on characteristics of the base material cleaning apparatus 52 according to Embodiment 2.

A transport means of the base material cleaning apparatus 52 according to Embodiment 2 includes a transport table 2B on which the base material 1 is mounted and moves the transport table 2B in the table transport direction T2 to perform the transport operation as in Embodiment 1.

The transport table 2B includes, in an upper layer portion thereof, an adsorption mechanism 5 that adsorbs a rear surface 1r of the base material 1. The base material cleaning apparatus 52 according to Embodiment 2 is characterized by the transport table 2B including the adsorption mechanism 5.

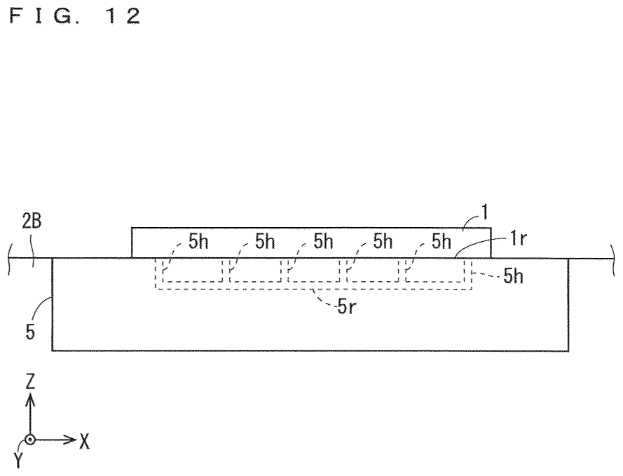

FIG. 12 is a schematic illustration of a structure of the adsorption mechanism 5. As illustrated in the figure, the adsorption mechanism 5 includes an adsorption path 5r and a plurality of adsorption holes 5h that communicate with the adsorption path 5r. The plurality of adsorption holes 5h are arranged at locations overlapping the rear surface of the base material 1 in plan view. The adsorption mechanism 5 includes the adsorption path 5r and the plurality of adsorption holes 5h and adsorbs the base material 1 from the rear surface 1r thereof using the plurality of adsorption holes 5h by vacuum adsorption.

In the base material cleaning apparatus 52 according to Embodiment 2, the cleaning mist gas MG2 obtained by the first air gas blowing performed by the air knife 23 is blown directly onto the front surface of the base material 1 as in Embodiment 1, so that the base material 1 mounted on the transport table 2B can move.

In the base material cleaning apparatus 52 according to Embodiment 2, the transport table 2B includes the adsorption mechanism 5, and the adsorption mechanism 5 adsorbs the base material 1 from the rear surface 1r thereof so that the base material 1 can stably and tightly be secured onto the transport table 2 even when receiving the cleaning mist gas MG2.

Furthermore, the adsorption mechanism 5 functions as a porous adsorption plate including the plurality of adsorption holes 5h, and thus, even when the base material 1 has a thin structure having a thickness of 1 mm or less, the base material 1 can tightly be secured onto the transport table 2 not to be moved by the cleaning mist gas MG2.

Furthermore, since the adsorption mechanism 5 functions as the porous adsorption plate, deformation of the base material 1 due to adsorption focused on a local portion and generation of a gap between a front surface of the adsorption mechanism 5 and the front surface 1s of the base material 1 due to deformation do not occur.

As described above, the base material cleaning apparatus 52 according to Embodiment 2 surely avoids deformation of the base material 1, generation of the gap, and the like to surely avoid a phenomenon of interference with a flow of the cleaning mist gas MG2 containing the cleaning solution mist MT.

In the base material cleaning apparatus 52 according to Embodiment 2, the adsorption mechanism 5 included in the transport table 2B adsorbs the base material 1 from the rear surface 1r thereof using the plurality of adsorption holes 5h, so that, when the cleaning mist gas MG2 and the air gas AG2 are blown directly onto the front surface as the cleaning surface of the base material 1, the base material 1 can stably be mounted on the transport table 2B. In this case, even when the base material 1 has a thickness of 1 mm or less, the base material 1 can stably be mounted on the transport table 2B.

Furthermore, the plurality of adsorption holes 5h are provided to overlap the rear surface of the base material in plan view, so that deformation of the base material 1 does not occur when the adsorption mechanism 5 adsorbs the base material 1. No gap is thus generated between the adsorption mechanism 5 and the rear surface 1r of the base material 1 due to deformation of the base material 1.

As a result, the base material cleaning apparatus 52 according to Embodiment 2 can supply the cleaning mist gas MG2 to the front surface of the base material 1 without any obstructions during the first air gas blowing performed by the air knife 23 as the first air gas blower, so that the object-to-be-removed 3 adhering to the front surface of the base material 1 can be removed with accuracy.

Furthermore, the base material cleaning apparatus 52 according to Embodiment 2 can supply the air gas AG2 to the front surface of the base material 1 without any obstructions during the second air gas blowing performed by the air knife 31 as the second air gas blower, so that the remaining object remaining on the front surface of the base material 1 can be removed with accuracy.

### Others

While the base material cleaning apparatus 51 according to Embodiment 1 and the base material cleaning apparatus 52 according to Embodiment 2 have been shown above as the base material cleaning apparatus according to the present disclosure, the present disclosure is not limited to these embodiments and can be changed without departing from the scope and the spirit of the present disclosure.

While water including pure water has been shown as the cleaning solution in the present embodiment, an alkaline degreasing solution (a solution including sodium hydroxide and phosphoric acid) and an acidic degreasing solution (a solution including sulfuric acid and hydrochloric acid) are contemplated as the cleaning solution. The alkaline degreasing solution and the acidic degreasing solution are effective cleaning solutions for the base material 1 requiring degreasing.

In addition, the base material cleaning apparatus according to the present disclosure is applicable to acid cleaning using a solution containing sulfuric acid as the cleaning solution, etching using a solution containing iron chloride (III) as the cleaning solution, surface modification using a solution containing a metal organic compound, such as TEOS, as the cleaning solution, resist removal using a solution containing sodium hydroxide as the cleaning solution, and the like.

While the plating solution is contemplated as the object-to-be-removed 3 in the present embodiment, solid particles, such as dirt, dust, and particles, an organic compound, such as oil, a metal inorganic compound, such as rust and a metal oxide film, and the like are contemplated as the object-to-be-removed 3.

An example of a plating object-to-be-removed represented by the plating solution includes a metal salt as a metal ion supply source. Copper sulfate and nickel sulfate are contemplated as the metal salt, for example.

While an aspect in which the mist jet 21 and the air knife 23 constituting the mist gas supply mechanism 20 are independent of each other has been shown in the above-mentioned embodiment, an aspect in which the mist gas supply mechanism 20 and the mist jet 21 are integrated can also be used as indicated by a dashed line in FIG. 6.

While the anti-mist diffusion plate 4 is disposed parallel to the table transport direction T2 (X direction), disposition of the anti-mist diffusion plate 4 is not limited to this disposition, and a direction in which the anti-mist diffusion plate 4 is disposed may significantly be inclined to the X direction. A shape of the anti-mist diffusion plate 4 is not limited to the planar shape.

Any shape and disposition of the anti-mist diffusion plate 4 can be set under a condition that enables the anti-mist diffusion plate 4 to form the diffusion suppression space in which diffusion of the cleaning solution mist MT contained in the cleaning mist gas MG2 can be prevented in a space region being in contact with the front surface 1s as the cleaning surface of the base material 1.

Furthermore, while the table transport direction T2 as a direction in which the base material 1 is transported is set to the horizontal direction along the X direction, the table transport direction T2 may significantly be inclined to the X direction. Furthermore, the table transport direction T2 may be set to the vertical direction along the Z direction. That is to say, the table transport direction T2 can be set to any direction on the condition that the cleaning mist gas MG2 is blown onto the front surface of the base material 1 during the transport operation.

While the cleaning surface of the base material 1 is the front surface 1s in the above-mentioned embodiment, the cleaning surface may be the rear surface 1r. In this case, components corresponding to the mist gas supply mechanism 20 and the draining mechanism 30 are arranged on a side of the rear surface 1r of the base material 1, and the cleaning mist gas is blown directly onto the rear surface 1r of the base material 1 by the first air gas blown by the first air gas blower corresponding to the air knife 23.

In the base material cleaning apparatus 52 according to Embodiment 2, an aspect in which the base material 1 and the transport table 2B are tightly secured may include an aspect in which a means of securing the base material 1 other than the adsorption mechanism 5 is provided under a condition that enables the base material 1 to be stably and tightly secured onto the transport table 2B even when receiving the cleaning mist gas MG2 and the air gas AG2 without interfering with a flow of the cleaning mist gas MG2.

While the present disclosure has been described in detail, the foregoing description is in all aspects illustrative and not restrictive. It is understood that numerous unillustrated modifications can be devised without departing from the scope of the present disclosure.

### EXPLANATION OF REFERENCE SIGNS

1 base material
2, 2B transport table
3 object-to-be-removed
4 anti-mist diffusion plate
5 adsorption mechanism
5h adsorption hole
11 ultrasonic atomizer
12 mist supply piping
20 mist gas supply mechanism
21 mist jet
21M mist jet movement mechanism
21R mist jet rotation mechanism
23, 31 air knife
23M air knife movement mechanism
23R air knife rotation mechanism
30 draining mechanism
51, 52 base material cleaning apparatus
AG1, AG2 air gas
MG1 relay mist gas
MG2 cleaning mist gas
MT cleaning solution mist

1. A base material cleaning apparatus comprising:
a transport means that performs transport operation of transporting a base material along a transport direction; and
a mist gas supply mechanism that supplies a cleaning mist gas containing cleaning solution mist obtained by misting a cleaning solution to clean a cleaning surface of the base material, wherein
a particle diameter of the cleaning solution mist is 15 μm or less,
the mist gas supply mechanism comprises:
a mist jet that jets a relay mist gas containing the cleaning solution mist along a mist jet direction; and
a first air gas blower that performs first air gas blowing of blowing a first air gas toward the relay mist gas along a first air gas blowing direction to merge the first air gas with the relay mist gas to thereby obtain the cleaning mist gas during the transport operation performed by the transport means,
the cleaning mist gas is supplied to the cleaning surface of the base material by the first air gas blowing, and
a flow rate of the relay mist gas is set to an initial mist flow rate, a flow rate of the first air gas is set to a first air gas flow rate, and the first air gas flow rate is set to be higher than the initial mist flow rate.

2. The base material cleaning apparatus according to claim 1, wherein
the first air gas blower performs the first air gas blowing to blow the cleaning mist gas directly onto the cleaning surface of the base material.

3. The base material cleaning apparatus according to claim 2, further comprising
a second air gas blower that performs second air gas blowing of blowing a second air gas directly onto the cleaning surface of the base material during the transport operation performed by the transport means, the second air gas blower being disposed downstream of the first air gas blower in the transport direction.

4. The base material cleaning apparatus according to claim 2, further comprising:
an ultrasonic atomizer that applies an ultrasonic vibration to the cleaning solution to generate the cleaning solution mist; and
mist supply piping for supplying the cleaning solution mist generated by the ultrasonic atomizer to the mist jet.

5. The base material cleaning apparatus according to any claim 1, wherein
the first air gas blowing direction includes a component in a transport opposite direction opposite the transport direction, and
a first air gas blowing angle is set in a range of more than 0° and less than 90°, the first air gas blowing angle being an angle of the first air gas blowing direction relative to the transport direction.

6. The base material cleaning apparatus according to claim 5, having:
a first blower movement function of moving the first air gas blower; and
a first blowing angle adjustment function of adjusting the first air gas blowing angle.

7. The base material cleaning apparatus according to claim 5, wherein
the mist jet direction includes a component in the transport direction, and
a mist jet angle is set in a range of more than 0° and less than 90°, the mist jet angle being an angle of the mist jet direction relative to the transport direction.

8. The base material cleaning apparatus according to claim 7, having:
a jet movement function of moving the mist jet; and
a jet angle adjustment function of adjusting the mist jet angle.

9. The base material cleaning apparatus according to claim 1, further comprising
an anti-mist diffusion plate that is disposed between the mist gas supply mechanism and the cleaning surface of the base material, wherein
the anti-mist diffusion plate is disposed to provide a diffusion suppression space having a predetermined gap between the anti-mist diffusion plate and the cleaning surface of the base material without interfering with supply of the cleaning mist gas to the cleaning surface of the base material.

10. The base material cleaning apparatus according to claim 9, wherein
the predetermined gap is set to have a length exceeding the particle diameter of the cleaning solution mist.

11. The base material cleaning apparatus according to claim 2, wherein the transport means includes a transport table on which the base material is mounted and moves the transport table in the transport direction to perform the transport operation, the transport table includes an adsorption mechanism that adsorbs a rear surface of the base material, and the adsorption mechanism includes a plurality of adsorption holes that overlap the rear surface of the base material in plan view and adsorbs the base material from the rear surface thereof using the plurality of adsorption holes.
